(19) United States
(12) Patent Application Publication
(10) Pub. No.: US 2007/0063329 A1
(43) Pub. Date: Mar. 22, 2007

(54) Structure Of Memory Card Packaging And Method Of Forming The Same

(76) Inventors: Chin-Tong Liu, Hsinchu City (TW); Chin-Shu Wu, Jhubei City (TW)

Correspondence Address: Jason Z. Lin;Lin & Associates, Intellectual Property, Inc., Post Office Box 2339, Saratoga, CA, 95070-0339, US

(21) Appl. No.: 11/551,710

(22) Filed: Oct. 21, 2006

Related U.S. Application Data
(62) Division of application No. 11/146,545, filed on Jun. 7, 2005.

(30) Foreign Application Priority Data
Mar. 31, 2005 (TW) 094110252

(51) Int. Cl. H01L 23/02

(52) U.S. Cl. 257/679

(57) ABSTRACT

A structure and a method for a memory card are provided, including a circuit substrate and an encapsulating case. The substrate is completed with chips and circuit connected, and is stamped on the circumferential borders to form a plurality of ribs or gaps. The case is formed by a burying injection molding method on the top side of the substrate to encapsulate the ribs or gaps on the circumferential border of the substrate, so that the case and the substrate are tightly engaged. The structure of the memory card is stronger and water-proof.

### CROSS-REFERENCES TO RELATED APPLICATIONS

This is a division of U.S. patent application Ser. No. 11/146,545, filed Jun. 7, 2005.

### FIELD OF THE INVENTION

The present invention generally relates to a structure for packaging memory card, and a method of forming the same, and more specifically to a structure for packaging multimedia card (MMC) or secure digital (SD) card, and a method of forming the same.

### BACKGROUND OF THE INVENTION

As the consumer electronics such as digital camera, cellular phone and personal digital assistant (PDA), and multimedia audiovisual products become popular, the demand of small flash memory card also increases. The flash memory cards currently marketed can be categorized as Compact Flash (CF) card, Smart Media Card (SMC), Multimedia Card (MMC), Secure Digital (SD) card, and memory Stick (MS) card. The present invention is provided as an improvement over the structure of MMC and SD card.

FIG. 1 shows an exploded view of a conventional MMC or SD card, including a case 1, and a circuit substrate 2. Both case 1 and substrate 2 are manufactured separately. Substrate 2 includes all the chips, such as control chip and storage chip, and the required electrical connections are made. During the packaging of the MMC or SD card, case 1 is glued to cover the top side of substrate 2 so that the chips are sealed inside case 1. This forms the structure of a memory card. The main disadvantage of the structure is that case 1 is glued to the top side of substrate 2 around the border. This limited engagement is prone to worn-off after the repetitive inserting and removing the memory card from the consumer electronic devices, which will lead to the separation of the substrate 2 from case 1. In addition, this type of glue seal is usually not water-proof. Any water leakage can damage the memory card. Therefore, it is imperative to device an improvement of the structure of the conventional memory card packaging.

### SUMMARY OF THE INVENTION

The present invention has been made to overcome the aforementioned drawback of conventional MMC and SD card packaging. The primary object of the present invention is to provide a sturdy and water-proof structure of MMC and SD memory card. The structure of the present invention includes a burying injection molding method to form a case on the top side of the circuit substrate and encapsulate the chips and circuit inside the memory card. The protective case and the circuit substrate are tightly engaged to provide a higher structural strength as well as water-proof.

Another object of the present invention is to provide a structure of memory card with a larger memory capacity. When the exterior size is fixed, the structure of the memory card must provide a larger interior space in order to accommodate more memory chips. The structure of the present invention provides a larger interior space in comparison with the conventional structure.

To achieve the aforementioned objects, the present invention uses a circuit substrate with chips and circuit connected, and stamps the circumferential borders of the substrate to form a plurality of ribs or gaps. Then, a burying injection molding method is used to form a case on the top side of the substrate, and encapsulate the ribs or gaps on the circumferential border of the substrate, so that the case and the substrate are tightly engaged. During the injection molding, a protective mask is formed first. The protective mask is placed over the top side of the substrate, and the case is then formed over the mask and the substrate using injection molding.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows an exploded view of the structure of a conventional memory card;

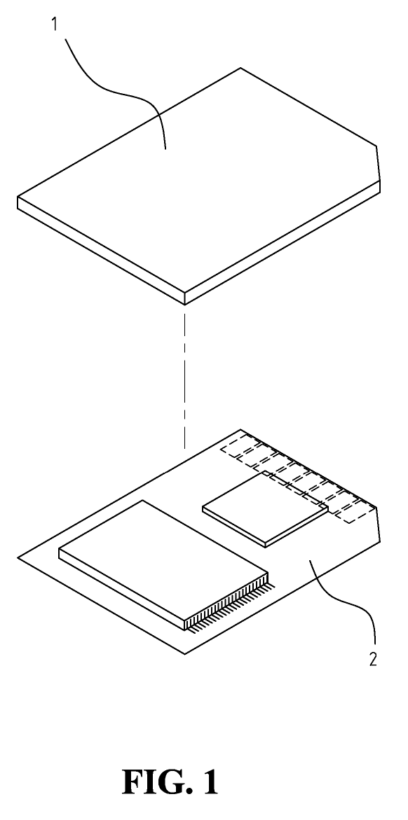

FIG. 2 shows a schematic view of the circuit substrate of the present invention;

FIG. 3 shows a 3D view of a memory card of the present invention;

FIG. 4 shows a cross-sectional view of a memory card of the present invention; and

FIG. 5 shows another embodiment of the circuit of the substrate of the present invention.

### DETAILED DESCRIPTION OF THE PREFERRED EMBODIMENTS

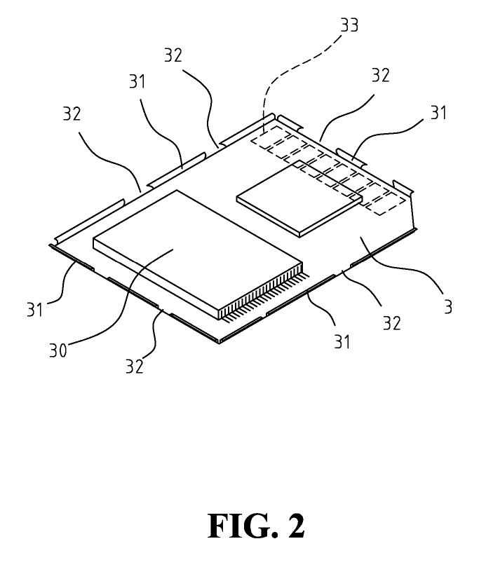

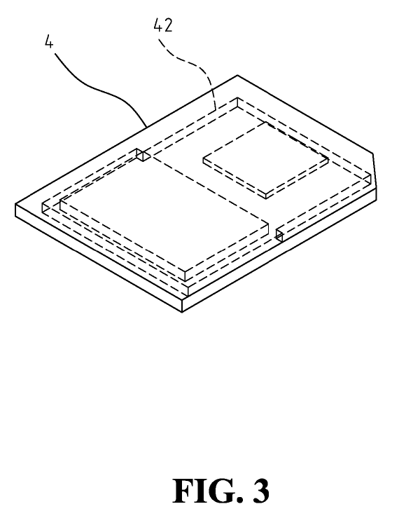

FIGS. 2, 3, and 4, show the three-dimensional view and the cross-sectional view of the substrate and the memory card of the present invention. The present invention is applicable to multimedia card (MMC) and secure digital (SD) card. The structure includes a circuit substrate 3 and a covering case 4.

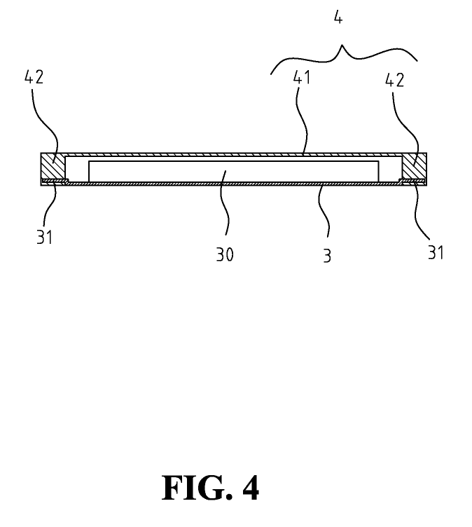

Substrate 3 includes a plurality of chips 30 and an electrically connected printed circuit board (PCB) with an electrical connection part 33. Because there is a thin copper layer embedded in the PCB, the present invention stamps the circumferential border of the PCB to form a plurality of ribs 31 and gaps 32. It is preferable to place ribs 31 and gaps 32 on at least two opposite sides of the substrate 3, or even three sides. As shown in FIG. 4, the locations of ribs 31 are tilted towards chips 30 of substrate 3. Ribs 31 are tilted. Ribs 31 are not at the same horizontal level as substrate 3, and they are preferably parallel to the surface of substrate 3. Gaps 32 are formed between two neighboring ribs 31. The shape of gaps 32 can be opening, a hole, or a conic opening, as shown in FIG. 2. The purpose of gaps 32 is to be filled with the material when forming case 4 so that the material of the case can hold ribs 31 to form a strong structure.

Case 4 can be made of acrylnitrie-butadience-styrenecopolymer (ABS) or polycarbonate (PC). The main structure of case 4 is formed using a burying injection molding method on the top side and the circumferential border of the substrate 3. The structure of case 4 includes a thin plate 41 and a border frame 42. Thin plate 41 and substrate 3 form a space for enclosing chips 30. The present invention allows the thickness of thin plate 41 to be reduced from 0.3 mm to 0.05-0.2 mm. Therefore, the interior space of the structure is larger than the conventional structure, and can accommodate more memory chips to meet the contemporary demands. Because a burying injection molding method is used to form case 4, frame 42 encapsulates the circumferential border of substrate 3, i.e., ribs 31. This ensures that substrate 3 and case 4 are tightly bound, and tightly sealed to provide the water-proof requirement.

The present invention also provides a method for forming the aforementioned structure. Before the packaging process, the border of substrate 3 is made to form a plurality of ribs 31 and gaps 32, as shown in FIG. 2. The electrical connections must also be made. The packaging method includes the steps of:
(A) injection molding a protective mask, which being smaller and thinner than the case; and
(B) placing the protective mask on the stop side of substrate 3 to cover the chips, and forming a case on the top side and the circumferential border of substrate 3 using a burying injection molding method so that the border of case 4 encapsulating ribs 31 of substrate 3 to form a structure of a memory card.
   The protective mask in step (A) can be a thin plate with strut extending downwards. The shape of the strut depends on the size and the shape of chips 30 on substrate 3. The purpose of the protective mask is to protect chips 30 from damages during step (B) of forming injection molding case 4. The protective mask will also be integrated with the material used in injection molding into case 4. The main structure of case 4 includes a frame 42, formed during the injection molding in step (B), encapsulating the border of substrate 3.

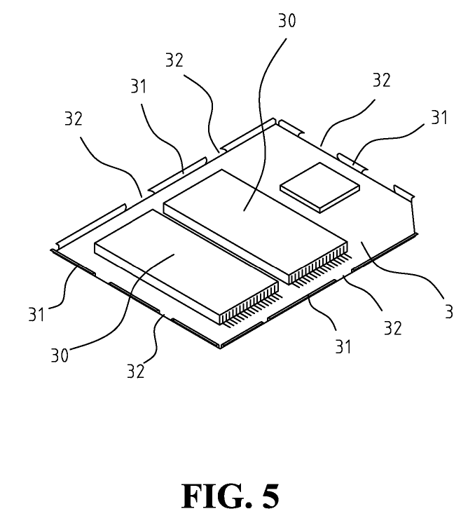

FIG. 5 shows another embodiment of the present invention. The difference is in the placement of chips 30 on substrate 3. As shown in FIG. 5, chips 30 include at least two memory chips and a control chip. The remaining structure is the same as the first embodiment, such as, including ribs 31 and gaps 32.

In comparison to conventional structure, the present invention includes the ribs and the gaps on the circumferential border of the substrate, which can be encapsulated in a case formed by a burying injection molding method so that the structure is stronger and provides more interior space. When applied to SD and MMC cards, the present invention is stronger and water-proof compared to the conventional packaging structure.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A packaging method for memory cards, applicable to a multimedia card (MMC) or secure digital (SD) card, forming a plurality of ribs and gaps on at least two opposite borders of a circuit substrate with chips and electrical connection, said method comprising the steps of:
(A) injection molding a protective mask; and
(B) placing said protective mask on the stop side of said substrate, and forming a case on the top side and the circumferential border of said substrate using a burying injection molding method so that the border of said case encapsulating said ribs of said substrate to form a structure of a memory card.

2. The method as claimed in claim 1, wherein said ribs are at a different level from the surface of said substrate.

3. The method as claimed in claim 1, wherein said ribs are concave and parallel to the surface of said substrate.

4. The method as claimed in claim 1, wherein said gaps are openings or holes.

5. The method as claimed in claim 1, wherein said ribs and said gaps are formed on at least three sides of said substrate.

6. The method as claimed in claim 1, further comprising a memory card manufactured by said method.
